(19) United States
(12) Patent Application Publication
(10) Pub. No.: US 2003/0209324 A1
(43) Pub. Date: Nov. 13, 2003

(54) Plasma reactor with reduced reaction chamber

(76) Inventor: Steven T. Fink, Mesa, AZ (US)

Correspondence Address: PILLSBURY WINTHROP, LLP, P.O. BOX 10500, MCLEAN, VA, 22102, US

(21) Appl. No.: 10/401,571

(22) Filed: Mar. 31, 2003

Related U.S. Application Data
(63) Continuation of application No. PCT/US01/32094, filed on Oct. 15, 2001.
(60) Provisional application No. 60/240,057, filed on Oct. 16, 2000.

(51) Int. Cl. C23F 1/00; C23C 16/00

(52) U.S. Cl. 156/345.48; 156/345.1; 118/723 I; 118/723 R

(57) ABSTRACT

A plasma reactor apparatus (100) includes plasma generating assembly (150) that is moveable between a first and second position. The plasma generating assembly (150) includes an inductive coil assembly (216) that is coupled to a source of RF energy. In the first position, access is provided for mounting a wafer (101) onto a chuck assembly (250). In the second position, the plasma generating assembly (150) and the substrate chuck assembly (250) form an enclosed area (300) about the wafer (101). Process gas is used to fill the enclosed space (300) while a vacuum is created in the enclosed space (300). RF energy is applied to the inductive coil (218) and plasma is formed in the enclosed space (300) in order to process the wafer (101).

This application is a Continuation of International Application PCT/US01/32094, filed on Oct. 15, 2001 and claims the benefit of U.S. Provisional Application 60/240,057, filed Oct. 16, 2000, the contents of both of which are incorporated herein by reference.

### BACKGROUND OF THE INVENTION

The present invention relates to plasma processing systems and more particularly to a plasma processing system with a reduced area plasma formation chamber.

As is known in the art, plasma reactors have been widely adopted for semiconductor manufacture. For example, plasma reactors provide the ability to etch material from or deposit various layers of material onto silicon wafers. Due to significant capital and operating expense of such equipment, even small improvements in the equipment or in the methods of using the equipment can lead to significant financial advantages. Semiconductor capital equipment manufacturers responsible for the creation of such improvements stand to significantly improve market share in this multi-billion dollar industry.

In the formation of integrated circuits (IC's), films of both conducting and nonconducting (insulating) material are often deposited upon the surface of a substrate, such as a semiconductor wafer. For instance, insulating films (i.e silicon dioxide, SiO₂) are deposited upon a semiconductor substrate to generate a non-conducting layer through which contacts or vias may be etched. Thereafter, conducting material (usually aluminum or copper) may be deposited to generate conductive and ohmic contacts between IC devices and, moreover, the conducting material may be deposited within a contact or via on a semiconductor wafer to create electrical interconnections across insulating layers. At present, state-of-the-art etch and deposition reactors require the formation of an ionized gas or “plasma” during the processing and fabrication of semiconductor devices, flat panel displays and other products.

For example, one well-known process for depositing thin dielectric films onto a substrate is known as plasma enhanced chemical vapor deposition (PECVD). PECVD is a process in which a thin film is deposited using chemical reactions between various ionized deposition or reactant gases at the surface of the substrate. In PECVD, reactant gases are injected in close proximity to a substrate inside a process chamber. Thereafter, a plasma is formed and the plasma dissociation chemistry generally leads to the production of the desired chemical specie to be deposited upon the substrate. The plasma further generates an ionized specie (i.e. positive argon ions) to bombard the substrate surface (when a substrate RF bias is applied) and aid the mobility of the deposited specie. Unused gaseous species are pumped away via a vacuum pump. Specific reaction products are deposited onto the surface of the substrate and adsorbed when subjected to light ion bombardment, forming a film, whereas other by-products of the deposition chemistry are pumped from the chamber. For example, a typical PECVD process for depositing SiO₂ onto a semiconductor substrate includes the introduction of silane (SiH₄) and N₂O into the process chamber wherein the product SiO₂ is adsorbed onto the wafer surface and the additional products diatomic hydrogen (H₂) and diatomic nitrogen (N₂) are pumped away.

Alternatively, in plasma enhanced dry etching (i.e. oxide etch), a process gas such as a mix of CₓF_{y}, argon and O₂ is injected into the vacuum chamber wherein a plasma is formed. As before, the plasma dissociation chemistry is tuned for optimal production of the chemical reactant suitable for chemically reacting with the substrate surface material to be etched (i.e. CF₂ for selective oxide etch). Moreover, the plasma further produces a population of positively charged ions (Ar⁺) and free electrons suitable for providing energy to the substrate surface to activate the etch chemistry. In general, a substrate RF bias is employed to attract ions to the substrate surface in a controllable, directional manner to provide an anisotropic etch for desired feature side-wall profiles.

In either case, the generation of plasma is accomplished using either a capacitively coupled plasma (CCP) reactor, an inductively coupled plasma (ICP) reactor or a combination thereof. More specifically, a plasma reactor generally includes a vacuum chamber to preserve the vacuum integrity of the processing environment, a vacuum pump to achieve the low processing pressures, a process gas injection apparatus (typically a shower-head gas inject electrode above the substrate), a support for the substrate which can also attract ions thereto (generally comprising a RF biasable chuck), and a plasma generator comprising either a biasable upper inject electrode (CCP) or an inductive coil (ICP) surrounding the processing region. For instance FIGS. 1A and 1B present pictorial schematics of a CCP and ICP process reactor, respectively, including a vacuum chamber 10, a substrate 12 set atop a RF biasable chuck 14, a processing region 16 formed by the injection of gas into a low pressure chamber that is evacuated by a vacuum pump 18 through an upper electrode 20 that is either powered from a RF power generator for a CCP source or grounded for an ICP source, and an inductive coil 22 for an ICP source.

As discussed above, the apparatus illustrated in FIGS. 1A and 1B, are utilized to form a plasma and tune the respective plasma chemistry to produce either the chemical reactants suitable for plasma etch or the chemical adatoms to be deposited upon the substrate surface. In either case, the plasma chemistry or dissociation condition for the plasma is sensitively determined by the plasma density and the gas residence time for the processing volume. The gas residence time can be defined as the ratio of the processing volume to the pumping speed delivered to the processing volume by the vacuum pump. In fact, the processing volume and respective pumping speed pre-determine a desirable range of plasma density acceptable to permit the optimum dissociation conditions for the etch or deposition process. Consequently, this restraint on the plasma density can lead to a restraint on the process in order to achieve process selectivity. This problem is particularly well-known in oxide plasma etch.

Given these design criteria, it is generally understood that volume reduction and pumping speed enhancement can lead to improved rates since the residence time can be reduced and the plasma density increased in order to maintain the same dissociation condition. However, current state-of-the art CCP and ICP reactors, as shown in FIGS. 1A and 1B, exhibit either poor pumping speed delivered to the processing region as in CCP reactors of FIG. 1A or large processing volumes as in the ICP reactor of FIG. 1B. These inherent problems associated with pumping through an annular region surrounding the substrate, amongst others, lead to limited process rates and unnecessary process restraints. Additionally, due to the corresponding vacuum design required to achieve acceptable process conditions in current apparatus, over-sized vacuum pumps and components are required leading to very large and expensive process hardware.

It would be advantageous therefore to have a plasma processing system that provided the ability to adjustably modify the volume of the reaction space contained inside the process chamber. It would be further advantageous to provide an ability to reduce the volume of the reaction space to allow improved process conditions and/or integration of a less expensive vacuum pump and associated gate valve.

### BRIEF SUMMARY OF THE INVENTION

According to one aspect of the present invention, a plasma processing apparatus is provided that includes a plasma generating assembly that is moveable between first and second positions. The apparatus further includes a chuck assembly configured to support a substrate that is to be plasma processed. The plasma generating assembly and the chuck assembly are configured such that when the plasma generating assembly is in the first position and the ambient pressure has been reduced to the pre-determined wafer transfer pressure, a substrate may be loaded onto or unloaded from the chuck assembly. When the plasma generating assembly is in the second position, an enclosed space is formed between the plasma generating assembly and chuck assembly such that the substrate, when loaded onto the chuck assembly, is within the enclosed space. A plasma may be formed by supplying ionizable gas to the enclosed space and energizing the plasma generating element of the plasma generating apparatus with RF energy. With such an arrangement, a reduction of the reaction space within a plasma reactor chamber may be achieved.

According to another aspect of the present invention, a method of plasma processing semiconductor wafers includes placing a wafer on a substrate chuck. After the wafer has been placed on the chuck, a plasma generating assembly is lowered into contact with the substrate chuck such that an enclosed area is formed around the wafer. Plasma gases, such as CₓF_{y} (e.g., C₄F₈), O₂ and Ar for oxide etch and SiH₄ and N₂O for oxide deposition, are injected into the enclosed area. Prior to process gas injection, the enclosed area is evacuated by means of a vacuum pump to achieve a base pressure and, once gas is introduced, a vacuum pump valve is adjusted to achieve a pre-determined process pressure. The plasma generating element is energized with RF energy sufficient to create and sustain plasma within said enclosed space. The wafer is then exposed to the plasma for a period of time sufficient to perform the particular plasma process, such as deposition, etching, or resist stripping. Once the particular process is complete, the enclosed space is evacuated of gas and returned to the pre-determined wafer transfer pressure. At this time, the plasma generating assembly is raised and the wafer is removed from the substrate chuck. With such a process, a wafer may be plasma processed in a reduced space inside a plasma reactor chamber.

### BRIEF DESCRIPTION OF SEVERAL VIEWS OF THE DRAWING

The above described and other features of the present invention will be described while referring to the accompanying drawings in which:

FIG. 1A is a pictorial schematic of a capacitively coupled plasma (CCP) reactor;

FIG. 1B is a pictorial schematic of an inductively coupled plasma (ICP) reactor;

FIG. 1C is a pictorial schematic of a plasma reactor according to the present invention;

FIG. 2 is a cross sectional view of the adjustable chamber portion, shown in the open position, of the plasma reactor of FIG. 1C;

FIG. 3 is a cross sectional view of the adjustable chamber portion, shown in the closed position, of the plasma reactor of FIG. 1C; and

FIG. 4 is a flowchart describing the method of using the plasma reactor of FIGS. 1C-3.

### DETAILED DESCRIPTION OF THE INVENTION

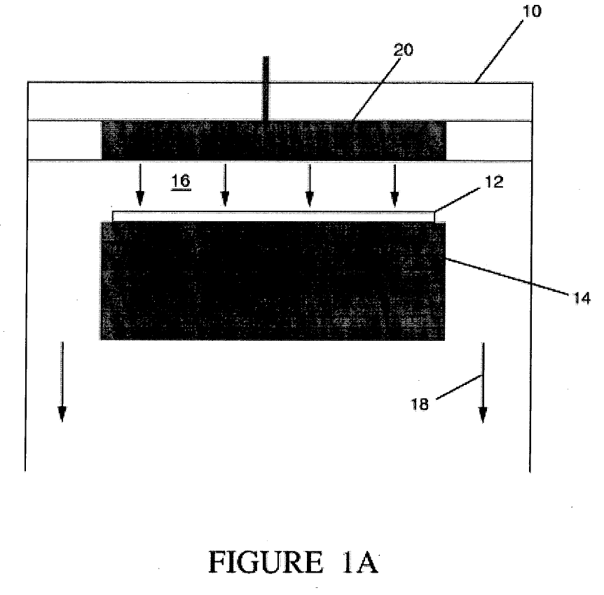

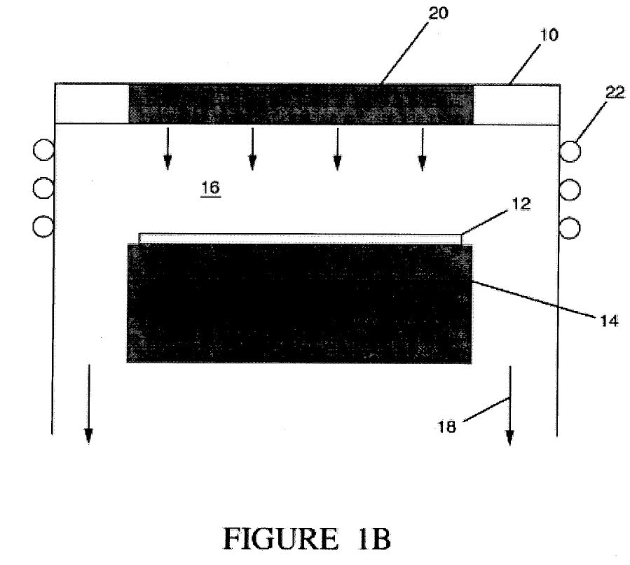

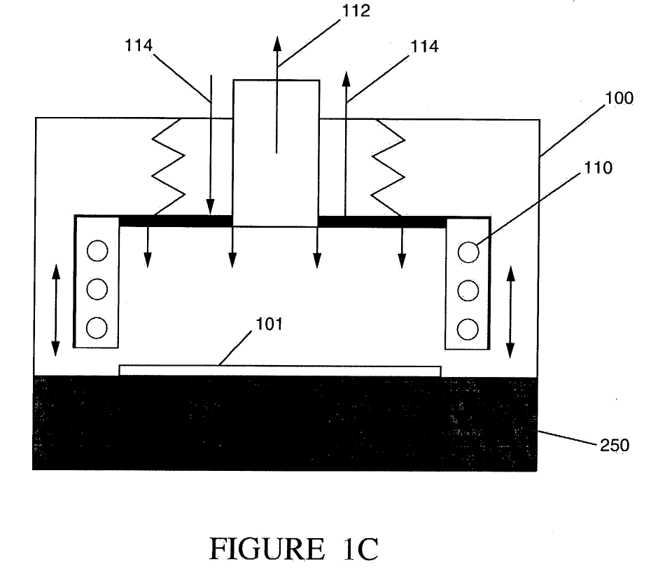

Referring now to FIG. 1C, a plasma reactor 100, i.e. an oxide etch reactor or PECVD reactor, is shown to include a plasma generating apparatus 110 and chuck assembly 250 for processing a substrate 101. Chamber 100 as shown in FIG. 1C corresponds to an inductively coupled plasma (ICP) type configuration. Chamber 100 is herein suitable for processing a substrate 101 which is typically a semiconductor wafer ranging from approximately 75 mm to 400 mm in diameter and approximately 0.1 mm to 1 mm thick.

There are several inputs to plasma generating apparatus 110 including process gas, RF power, vacuum pump (gate) valve control, vacuum pump control, and chuck cooling fluid. Outputs from plasma generating apparatus 110 include exhaust gas 112 and cooling fluid 114. The chuck 250 includes several additional components including an electrostatic clamp electrode, gas distribution system for wafer backside gas, RF bias electrode, and cooling system; the design of which is well-known to those skilled in the art.

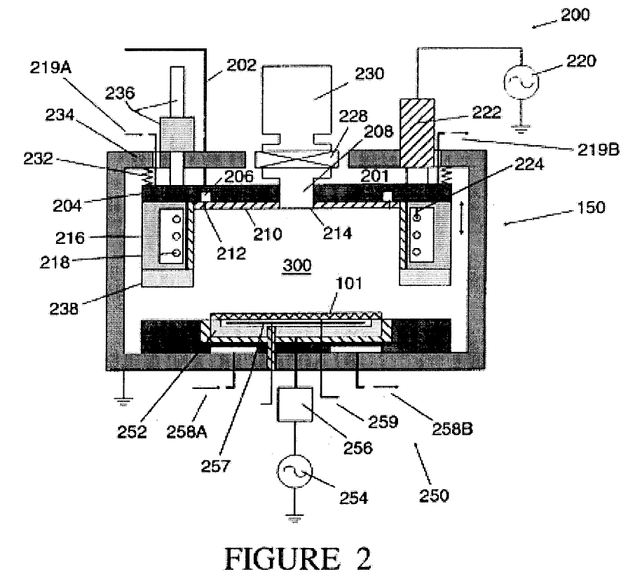

More particularly, and referring now to FIG. 2, a detailed view of chamber 100 according to a preferred embodiment of the present invention is shown to include plasma reactor 200 which is here depicted in the open position. Plasma reactor 200 comprises plasma generating assembly 150 and chuck apparatus 250. Plasma reactor 200 further includes gas line 202 coupled to gas plenum plate 204 and gas plenum 206 of plasma generating assembly 150. Shower-head gas injection plate 210 is coupled to gas plenum plate 204 and includes a plurality of apertures 212 through which gas is distributed. Plasma generating assembly 150 further includes an inductive coil assembly 216, which is herein an annular configuration, coupled to the lower surface of gas plenum plate 204 at its periphery. A vacuum pump 230 is coupled to the backside of gas plenum plate 204 with a valve 228 disposed between vacuum pump 230 and gas plenum plate 204. A bellows 232 is coupled between plasma generating assembly 150 and upper wall of chamber 234.

Gas line 202 serves as a conduit for process gas located external to plasma reactor 200. Gas line 202 passes through upper wall of chamber 234 and through area 201 created by bellows 232, and couples to gas plenum plate 204. Note that area 201 will be at atmospheric pressure whereas the processing area 300 will typically be at reduced pressure. Further to the gas connections, gas line 202 attaches to gas plenum plate 204 such that the gas flowing through gas line 202 passes evenly into plenum 206 as will be described in more detail below. Gas line 202 is preferably made of a material such as stainless steel and it is capable of carrying reactant gases such as C₄F₈, CF₄, Cl₂, HBr, silane, etc. as well as inert gases such as Ar, He, etc.

Gas plenum plate 204 may have a generally disc-like or circular shape having a thickness of several centimeters, which is preferably constructed from a material such as aluminum. As mentioned above, gas plenum plate 204 further includes plenum 206 and a relatively large exhaust aperture 208 (of order several inches in diameter). The exhaust aperture 208 passes concentrically through the center of gas plenum plate 204, through the vacuum valve 228 and it is pneumatically connected to the input of the vacuum pump 230. Alternatively, a plurality of relatively large exhaust apertures (not shown) can be distributed about the lower surface of the plasma generating apparatus 150. If a plurality of exhaust apertures are employed for increased pumping speed, they may extend through the gas plenum plate 204 where they are pneumatically connected to a common chamber volume prior to entrance to the vacuum valve 228 and vacuum pump 230. As will be described in more detail below, plenum 206 provides an even distribution of the process gas through gas plenum plate 204 to a plurality of injection apertures 212 in shower-head gas injection plate 210. Gas plenum plate 204 is preferably connected and sealed concentrically to the bottom side of bellows 232 as shown in FIG. 2. Like gas plenum plate 204, bellows 232 is generally circular or annular in shape, and it is preferably made of a material such as stainless steel. Similar to its connection to the upper surface of the gas plenum plate 204, it is preferably connected and sealed to the bottom side of the upper wall of chamber 234. Bellows 232 serves to isolate area 201 from the remainder of plasma generating device 200 (or more specifically, the processing area 300) while allowing plasma generating assembly 150 to traverse a path indicated by direction arrows in FIG. 2. Bellows 232 may be a prefabricated unit since vacuum bellows are well known to those of skill in the art and are commonly available for integration into plasma reactor systems such as those described herein.

According to the present invention, plasma reactor 200 includes a vertically movable plasma generating assembly 150 capable of reducing the plasma generation volume. As will be described in more detail below, by lowering the plasma generating assembly 150 such that spacer ring 238 is in sufficient contact with upper surface of chuck assembly 250 to form a vacuum seal and provide good electrical contact, a processing area 300 is created about substrate 101. According to the preferred embodiment, drive mechanism 236 is preferably a lead screw driven linear stage capable of providing vertical movement of plasma generating assembly 150 relative to chuck assembly 250. In general, the system may require three drive mechanisms 236 spaced at equal distances azimuthally, i.e. every 120 degrees (only one drive mechanism 236 is shown in FIG. 2). Since linear drive mechanism components are well known in the art and are readily available for integration into the apparatus of the present invention the details of these components, including lead screws, linear bearings, electrical drive motors, controllers, limit switches, and the like will not be described. It will be appreciated by those of skill in the art that different methods of providing vertical translation of electrode assembly 150 relative to chuck assembly 250 (e.g. linear motors) may be provided and such methods fall within the scope of the invention. Furthermore, as an alternative, chuck assembly 250 may move relative to a stationary plasma generating assembly 150 rather than the inverse.

Like gas plenum plate 204, shower-head gas injection plate 210 is generally disc-like or circular in shape having a thickness of approximately 1 cm. Shower plate 210 may be rigidly attached concentrically to the bottom side of gas plenum plate 204 such that exhaust aperture 214 aligns concentrically to exhaust aperture 208 of gas plenum plate 204. It is preferably made of a material such as aluminum. However, shower-head gas injection plate 210 may be anodized or covered by a protective plate made from silicon, silicon carbide, quartz, carbon, alumina, etc. to reduce contamination. Therein, the protective plate further includes an exhaust aperture (not shown) and a plurality of gas injection apertures (not shown) properly aligned with exhaust aperture 214 and gas inject apertures 212 in shower-head gas injection plate 210. For example, in oxide etch applications, the protective plate may be fabricated from silicon and, since the plate will be etched, it may serve the purposes of reducing substrate contamination and providing a source of silicon for scavenging fluorine radicals. Cladding the interior surface of a plasma reactor with materials beneficial to the process is well-known to those of skill in the art. Such practices are incorporated herein where applicable. According to the preferred embodiment, gas inject apertures 212 follow an evenly distributed pattern across the bottom surface of the shower-head gas injection plate 210, providing an even distribution of process gas across substrate 101 during the formation of a plasma. For those gas inject apertures lying within the radius of the gas plenum 206, gas channels (not shown) are machined radially inward within gas plenum plate 204 in order to distribute gas to the interior gas inject apertures. A typical gas injection system may comprise from 1 to several thousand gas inject apertures with a diameter (at its smallest cross-section) ranging from 0.1 to several millimeters. Other configurations and/or distribution patterns of gas inject apertures may be employed to provide other gas flow characteristics within the plasma reactor chamber formed within the enclosed area 300 (FIG. 2).

Valve 228 (or the plurality of valves; not shown) may be of the gate type manufactured by VAT Valve and MDC Vacuum Products Corporation. One such example of a gate valve offered by MDC is the model GV-4000M-P (4 inch DIA gate valve). The purpose of gate valve 228 is to allow the vacuum pump inlet to pneumatically access the process chamber when in the open position, isolate the vacuum pump from the process chamber when in the closed position and throttle the vacuum pump when in the partially open position. Valve 228 is preferably attached to gas plenum plate 204 such that exhaust gas may pass through exhaust aperture 208 and into vacuum pump 230. Vacuum pump 230 may be, for example, one manufactured by Osaka (TH350, 350 l/sec TMP). There are a number of TMP and gate valve manufacturers known to those of ordinary skill in the art. A larger vacuum pump may be employed if necessary.

Still referring to FIG. 2, inductive coil assembly 216 of plasma generating assembly 150 is generally annular in shape with a wall height of several inches for a quarter-wave helical resonator at 13.56 MHz. Inductive coil assembly 216 further includes a RF coil 218 immersed within a bath of (dielectric) coolant such as Fluorinert and disposed about the perimeter of a dielectric process tube which interfaces with the plasma processing region 300. The bath of coolant is recirculated via an inlet flow of coolant 219A and a corresponding outlet flow of coolant 219B through coolant supply lines in order to provide plasma source cooling. A slotted electrostatic shield may be employed to reduce capacitive coupling between the inductive coil 218 and the plasma processing region 300. RF power is coupled to the inductive coil 218 from a RF generator 220 through an impedance match network 222 to the coil tap 224. The bath of coolant is recirculated via an inlet coolant flow (not shown) and a corresponding outlet coolant flow (not shown). Inductive coil assembly 216 is preferably concentrically attached to gas plenum plate 204 such that their respective outer surfaces are aligned as shown in FIG. 2. The electrical and mechanical design of an inductive coil assembly including the inductive coil, electrostatic shield, process tube, coil enclosure, impedance match network, tap location, etc. is well known to those of skill in the art.

In order to adjust the height of the plasma processing region 300, a spacer ring 238 may be inserted between the bottom surface of the inductive coil assembly 216 and the upper surface of the chuck assembly 250. It has a generally annular configuration substantially similar to inductive coil assembly 216 with a thickness ranging from 1 cm to several centimeters. It is preferably fabricated from anodized aluminum. Spacer ring 238 is herein removably coupled to the bottom surface of inductive coil assembly 216.

As mentioned above, plasma reactor 200 includes a chuck assembly 250 having a primary function of serving to support substrate 101 during plasma processing thereof. Chuck assembly 250 further includes a RF biasable chuck electrode 252 that enables the application of a RF bias to the substrate for adjustment of the ion energy. RF power is coupled to the chuck bias electrode 252 from chuck RF generator 254 through chuck impedance match network 256. Additional components housed within the chuck assembly 250 include an electrostatic electrode 257, chuck cooling system inlet 258A and outlet 258B, and substrate backside gas (helium) distribution system 259. The electrical and mechanical design of a wafer chuck assembly is well known to those of skill in the art.

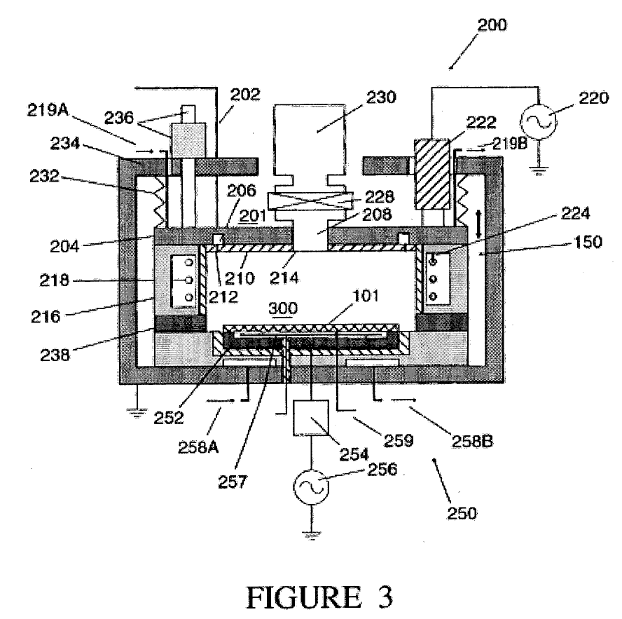

Referring now to FIG. 3 a detailed view of plasma reactor 200 is shown in the closed position. As can be seen in FIG. 3, shower-head gas inject plate 210, inductive coil assembly 216, spacer ring 238, and chuck assembly 250 create plasma processing region 300. As mentioned earlier, spacer plate 238 is removably coupled to inductive coil assembly 216. This provides the option of replacing spacer ring 238 with another spacer ring having a different thickness to effectively modify the volume of region 300. In accordance with the preferred embodiment, the distance between the top surface of substrate 101 and the bottom surface of shower-head gas inject plate 210 may vary between several centimeters and ten's of centimeters depending upon the process.

When plasma reactor 200 assumes the closed position as shown in FIG. 3, a base pressure of 10⁻⁷ to 10⁻⁵ Torr must be achievable within plasma processing region 300. Vacuum seals are achieved in conventional process chambers employing elastomer O-ring seals (not shown) resistant to outgassing and raised temperatures as high as 100° C. to 200° C. O-ring material such as Buna-N™ (<80 C.), Viton™ (<150 C.), Polyimide™ (<200 C.), silicone, Teflon™ (<150 C.) and Kalrez™, manufactured by Dupont, are elastomers that will seal a vacuum chamber with varying degrees of temperature resistance, outgassing rates, and permeability, etc. Depending upon the vacuum system specifications, an appropriate elastomer may be chosen.

While plasma generating device is in the closed position, the interface between plasma generating assembly 150 and chuck assembly 250 must provide for good electrical contact. Electrical contact is accomplished by ensuring a conductive contact between spacer ring 238 and chuck assembly 250. Conventional process chambers typically employ metal-clad O-ring seals such as a Spira-Shield™, manufactured by Magnetic Shield Corporation, to provide proper electrical contact. A similar type of O-ring seal may be used between spacer ring 238 and chuck assembly 250.

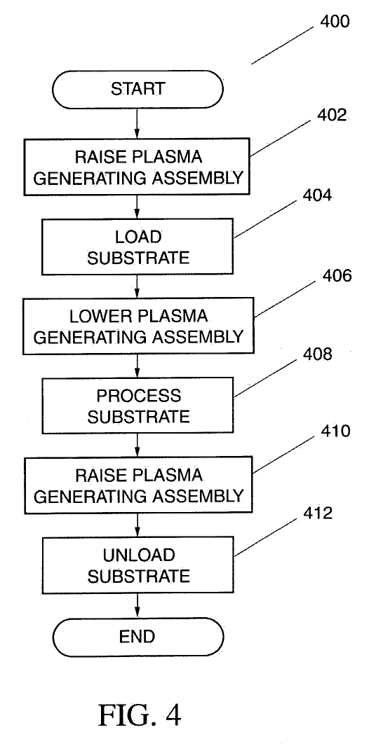

The preferred method of operation of plasma reactor 200 will now be described while referring to FIG. 3 and FIG. 4. It should be noted that operation of plasma reactor 200 is most preferably accomplished under computer control. That is, a control system (not shown) is coupled to plasma reactor 200 and to all of the various systems (e.g. wafer handling, temperature control, vacuum control, gas control, RF power control, match network control, etc.) associated with its operation. Since the basic operation of these systems are known to those of skill in the art, they will not be described in detail here. FIG. 4 is a flowchart of the steps associated with operating plasma reactor 200. Starting at step 402, drive mechanism 236 receives instructions from the control system (not shown) and raises the plasma generating assembly 150 away from chuck assembly 250 (if it is not already in that position, in which case step 402 is skipped). Then, at step 404, a substrate 101 is loaded onto chuck assembly 250 in the usual fashion. Lift pins from within the chuck assembly 250 are raised to receive substrate 101. The lift pins proceed to lower substrate 101 to the surface of chuck assembly 150, wherein an electrostatic clamping force is applied and a gas (preferably helium) is distributed to the back side of substrate 101.

After the substrate 101 is successfully loaded and clamped to chuck assembly 250, operation of plasma reactor system 200 moves to step 406 where drive mechanism 236 lowers plasma generating assembly 150 onto chuck assembly 250. It will be appreciated by those of skill in the art that drive mechanism 236 may be instructed to lower electrode assembly 150 a preset distance by the control system (not shown). Alternately, limit switches or sensing of electrical contact between spacer ring 238 and chuck assembly 250 may be employed to determine when plasma generating assembly 150 has been lowered a sufficient distance. Bellows 232 compresses and/or expands to allow for co-planarity mismatch between chuck assembly 250 and plasma generating assembly 150, and it preserves the vacuum integrity between regions 201 and 300. Once chuck assembly 250 and spacer ring 238 come into contact, chuck assembly 250 and plasma generating assembly 150 establish proper electrical contact.

After plasma generating assembly 150 has been lowered into position, step 408 proceeds with the commencement of processing according to conventional practice, i.e. a stored process recipe. In particular, the processing region is evacuated to the chamber base pressure, the process gas such as SiH₄, N₂O, CₓF_{y}, Ar, O₂, etc. is introduced to reaction space 300 through gas line 202, plenum 206 and gas inject apertures 212, the specified process pressure is achieved via adjustment of the vacuum pump valve 228, RF power is coupled to the inductive coil 218 through match network 222 and the plasma is formed. The process is carried out for a desired period of time or until an end-point diagnostic determines the end of the process.

Once the substrate processing has been completed, the chamber is evacuated, purged with an inert gas and the chamber pressure is equilibrated with the transfer chamber pressure. At step 410, drive mechanism 236 raises plasma generating assembly 150 away from chuck assembly 250. In step 412, substrate 101 is unloaded from chuck assembly 250. Prior to unloading substrate 101, the backside gas flow is shut off, the electrostatic clamping force is removed, and wafer 101 is lifted to the plane of the transfer arm via lift pins housed within the chuck assembly 250. The electrostatic clamp must first be disengaged before unloading substrate 101. Human operators or automation equipment usually perform the unloading step, neither of which are shown. Process 400 terminates after step 412.

Throughout the discussion of FIG. 2 through FIG. 4, the plasma generating assembly 150 has been shown to comprise an inductively coupled plasma (ICP) device. Alternatively, the plasma generating assembly may comprise a capacitively coupled plasma (CCP) electrode or an electron-cyclotron resonance (ECR) plasma source.

The many features and advantages of the present invention are apparent from the detailed specification and thus, it is intended by the appended claims to cover all such features and advantages of the described method which follow in the true spirit and scope of the invention. Further, since numerous modifications and changes will readily occur to those of ordinary skill in the art, it is not desired to limit the invention to the exact construction and operation illustrated and described. Accordingly, all suitable modifications and equivalents should be considered as falling within the spirit and scope of the invention as claimed.

What is claimed is:

1. A plasma processing apparatus comprising:
a plasma generating assembly moveable between first and second positions; and
a chuck assembly configured to support a substrate to be plasma processed, said plasma generating assembly and said chuck assembly configured such that when said plasma generating assembly is in said first position, said substrate may be loaded onto said chuck assembly, and when said plasma generating assembly is in said second position, an enclosed space is formed between said plasma generating assembly and said chuck assembly such that said substrate, when loaded on said chuck assembly, is within said enclosed space.

2. The plasma processing apparatus according to claim 1 further comprising:
a source of RF energy coupled to said plasma generating assembly;
a gas supply system coupled to said plasma generating assembly and operable to supply gas within said enclosed space; and
a vacuum system coupled to said plasma generating assembly and operable to create a vacuum within said enclosed space.

3. The plasma processing apparatus according to claim 2 wherein said plasma generating assembly further comprises:
a first plate having a plenum therein coupled to said gas supply system;
a second plate disposed on a surface of said first plate having an aperture therethrough, said aperture being in fluid communication with said plenum and said enclosed space;
an inductive coil disposed upon and about the perimeter of a bottom surface of said second plate; and
a spacer ring removably coupled to a lower surface of said inductive coil such that when said plasma generating assembly is in said second position, said spacer ring is in contact with said chuck assembly.

4. The plasma processing apparatus according to claim 3 wherein:
said first and second plates are generally circular in shape;
said inductive coil is a ring having an outer diameter substantially the same as an outer perimeter of said first plate and an inner diameter less than said outer diameter, said inductive coil further including:
an outer wall defined by said outer diameter and having a height defined by the distance between said bottom surface of said second plate and a top surface of said spacer ring, and
an inner wall defined by said inner diameter and having a height defined by the distance between said bottom surface of said first plate and a top surface of said spacer ring.

5. The plasma processing apparatus according to claim 4 wherein said inductive coil further includes an RF coil disposed between said inner and outer walls, said RF coil being coupled to said source of RF energy.

6. The plasma processing apparatus according to claim 4 wherein said inductive coil further comprises:
at least one cooling supply aperture in fluid communication with a space between said inner wall and said outer wall; and
at least one cooling exhaust aperture in fluid communication with said space between said inner wall and said outer wall.

7. The plasma processing apparatus according to claim 2 wherein said substrate chuck is coupled to said source of RF energy and further comprises:
cooling fluid supply and exhaust ports;
electrostatic clamp electrode; and
substrate backside gas supply and exhaust ports.

8. A method of plasma processing semiconductor wafers comprising:
placing a wafer on a substrate chuck;
lowering a plasma generating assembly into contact with said substrate chuck such that an enclosed area is formed around said wafer by surfaces of said plasma generating assembly and said substrate chuck;
supplying plasma gas within said enclosed area;
creating a vacuum in said enclosed area;
energizing said plasma generating component with RF energy to create a plasma within said enclosed area;
raising said plasma generating assembly when said wafer has been sufficiently processed; and
removing said wafer from said substrate chuck.

9. The method according to claim 8 further comprising:
energizing said substrate chuck with said RF energy; and
cooling said plasma generating assembly and said substrate chuck with cooling fluid.

10. The method according to claim 8 wherein said plasma gas includes one or more gases chosen from the group consisting of Cl₂, HBr, CF₄, C₄F₈, C₅F₈, Ar, O₂, SiH₄, N₂O and ammonia.

11. A plasma reactor system comprising:
a plasma reactor chamber;
a source of RF energy;
a substrate handling system;
a plasma generating assembly disposed within said reactor chamber and moveable between first and second positions, said plasma generating assembly coupled to said source of RF energy; and
a chuck assembly disposed within said reactor chamber configured to support a substrate to be plasma processed, said plasma generating assembly and said chuck assembly configured such that when said plasma generating assembly is in said first position, said substrate may be loaded onto said chuck assembly, and when plasma generating assembly is in said second position, an enclosed space is formed between said plasma generating assembly and said chuck assembly such that said substrate, when loaded on said chuck assembly, is within said enclosed space.

12. The plasma reactor system according to claim 11 further comprising:
a gas supply system coupled to said plasma generating assembly and operable to supply plasma gas within said enclosed space; and
a vacuum system coupled to said plasma generating assembly and operable to create a vacuum within said enclosed space.

13. The plasma reactor system according to claim 11 wherein said plasma generating assembly further comprises:
a first plate having a plenum therein coupled to said gas supply system;
a second plate disposed on a surface of said first plate having an aperture therethrough, said aperture being in fluid communication with said plenum and said enclosed space;
an inductive coil disposed upon and about the perimeter of a bottom surface of said second plate; and
a spacer ring removably coupled to a lower surface of said inductive coil such that when said plasma generating assembly is in said second position, said spacer ring is in contact with said chuck assembly.

14. The plasma reactor system according to claim 13 wherein:
said first and second plates are generally circular in shape; and
said inductive coil is a ring having an outer diameter substantially the same as an outer perimeter of said first plate and an inner diameter less than said outer diameter, said inductive coil further including:
an outer wall defined by said outer diameter and having a height defined by the distance between said bottom surface of said second plate and a top surface of said spacer ring, and
an inner wall defined by said inner diameter and having a height defined by the distance between said bottom surface of said second plate and a top surface of said spacer ring.

15. The plasma reactor system according to claim 13 wherein said inductive coil further includes an RF coil disposed between said inner and outer walls, said RF coil being coupled to said source of RF energy.

16. The plasma reactor system according to claim 12 wherein said substrate chuck is coupled to said source of RF energy and further comprises:
cooling fluid supply and exhaust ports;
electrostatic clamp electrode; and
substrate backside gas supply and exhaust ports.
